(19) United States
(12) Patent Application Publication
(10) Pub. No.: US 2025/0055531 A1
(43) Pub. Date: Feb. 13, 2025

(54) CHANNEL STATE INFORMATION (CSI) COMPRESSION FEEDBACK METHOD AND APPARATUS

(71) Applicant: BEIJING XIAOMI MOBILE SOFTWARE CO., LTD., Beijing (CN)

(72) Inventors: Dong CHEN, Beijing (CN); Liangang CHI, Beijing (CN)

(73) Assignee: BEIJING XIAOMI MOBILE SOFTWARE CO., LTD., Beijing (CN)

(21) Appl. No.: 18/719,198

(22) PCT Filed: Dec. 14, 2021
(86) PCT No.: PCT/CN2021/138032

§ 371 Date: Jun. 12, 2024

(51) Int. Cl. H04B 7/06; H04B 7/0452; H04B 7/0456

(52) U.S. Cl. CPC H04B 7/0626; H04B 7/0452; H04B 7/0478

(57) ABSTRACT

A channel state information (CSI) compression feedback method includes: obtaining an estimated CSI image H of a network device, and generating a temporal CSI image Hₑ according to the estimated CSI image H; compressing the temporal CSI image Hₑ to generate a feature codeword; and sending the feature codeword to the network device.

### CROSS REFERENCE TO RELATED APPLICATION

This application is the U.S. national phase application of International Application No. PCT/CN2021/138032, filed on Dec. 14, 2021, the entire contents of which are incorporated herein by reference for all purposes.

### TECHNICAL FIELD

The disclosure relates to a field of communication technology, more particularly, to a channel state information (CSI) compression feedback method and a CSI compression feedback apparatus.

### BACKGROUND

With the development of the 5th generation wireless communication networks, massive Multiple-Input Multiple-Output (mMIMO) has become a key technology. By configuring a large number of antennas, the mMIMO not only greatly improves a channel capacity under limited spectrum resources, but also has a strong anti-interference capability. In order to better use the mMIMO technology, a transmitter may obtain channel state information (CSI). In a system, a terminal estimates CSI of a downlink channel and then feeds back the CSI to a network device through a feedback link with a fixed bandwidth.

### SUMMARY

According to a first aspect of embodiments of the disclosure, a CSI compression feedback method, performed by a terminal, is provided. The method includes:
obtaining an estimated CSI image H of a network device, and generating a temporal CSI image H_{c} according to the estimated CSI image H;
compressing the temporal CSI image H_{c} to generate a feature codeword; and
sending the feature codeword to the network device.

According to a second aspect of embodiments of the disclosure, a CSI compression feedback method, performed by a network device, is provided. The method includes:
receiving a feature codeword sent by a terminal;
restoring the feature codeword to obtain a restored temporal CSI image H_{c}; and
obtaining an estimated CSI image Ĥ of the terminal according to the restored temporal CSI image Ĥ_{c}.

According to a third aspect of embodiments of the disclosure, a communication device is provided. The communication device includes: a processor and a memory having a computer program stored thereon. The processor executes the computer program stored in the memory, to cause the communication device to implement the method described in the first aspect above.

According to fourth aspect of embodiments of the disclosure, a communication device is provided. The communication device includes: a processor and a memory having a computer program stored thereon. The processor executes the computer program stored in the memory, to cause the communication device to implement the method described in the second aspect above.

### BRIEF DESCRIPTION OF THE DRAWINGS

In order to clearly illustrate technical solutions of embodiments of the disclosure or background technologies, a description of drawings used in the embodiments or the background technologies is given below.

FIG. 1 is a schematic diagram of a communication system of an embodiment of the disclosure.

FIG. 2 is a flowchart of a channel state information (CSI) compression feedback method of an embodiment of the disclosure.

FIG. 3 is a flowchart of a CSI compression feedback method of an embodiment of the disclosure.

FIG. 4 is a flowchart of a CSI compression feedback method of an embodiment of the disclosure.

FIG. 5 is a flowchart of a CSI compression feedback method of an embodiment of the disclosure.

FIG. 6 is a flowchart of a CSI compression feedback method of an embodiment of the disclosure.

FIG. 7 is a flowchart of a CSI compression feedback method of an embodiment of the disclosure.

FIG. 8 is a flowchart of a CSI compression feedback method of an embodiment of the disclosure.

FIG. 9 is a flowchart of a CSI compression feedback method of an embodiment of the disclosure.

FIG. 10 is a flowchart of a CSI compression feedback method of an embodiment of the disclosure.

FIG. 11 is a flowchart of a CSI compression feedback method of an embodiment of the disclosure.

FIG. 12 is a flowchart of a CSI compression feedback method of an embodiment of the disclosure.

FIG. 13 is a flowchart of a CSI compression feedback method of an embodiment of the disclosure.

FIG. 14 is a flowchart of a CSI compression feedback method of an embodiment of the disclosure.

FIG. 15 is a flowchart of a CSI compression feedback method of an embodiment of the disclosure.

FIG. 16 is a flowchart of a CSI compression feedback method of an embodiment of the disclosure.

FIG. 17 is a block diagram of a communication device of an embodiment of the disclosure.

FIG. 18 is a block diagram of a communication device of an embodiment of the disclosure.

FIG. 19 is a block diagram of a chip of an embodiment of the disclosure.

### DETAILED DESCRIPTION

For ease of understanding, terms involved in this disclosure are introduced at first.

### 1. CHANNEL STATE INFORMATION (CSI)

In the field of wireless communications, CSI is a propagation characteristic of a communication link. It describes a signal attenuation factor on each transmission path in a communication link, i.e., a value of each element in a channel gain matrix, such as, signal scattering, environment attenuation, distance attenuation and other information. The CSI enables a communication system to adapt to a current channel condition and provides a guarantee for high-reliability and high-speed communication in a multi-antenna system.

The CSI is categorized into CSI on a transmitter side and CSI on a receiver side depending on an application location. Generally, the CSI on the transmitter side can be used to compensate for the attenuation in advance through means such as power allocation, beam forming and antenna selection, to complete high-speed and reliable data transmission.

### 2. MASSIVE MULTIPLE-INPUT MULTIPLE-OUTPUT (MMIMO)

The mMIMO technology refers to using multiple transmitting and receiving antennas at the transmitter and the receiver, respectively, so that signals can be transmitted and received through the multiple antennas at the transmitter and the receiver, thereby improving the communication quality. The mMIMO can make full use of spatial resources, and exponentially improve a communication capacity of the system without increasing the spectral resources and the antenna transmission power.

The mMIMO technology has been used in the 4th generation (4G) communication and is intended to be used more widely in the 5th generation (5G) communication. The mMIMO in 4G communication has a maximum of 8 antennas, while 16/32/64/128 or even more massive antennas may be realized in 5G.

The mMIMO technology has following advantages: high multiplexing gain and diversity gain, high energy efficiency, and high spatial resolution. With respect to the high multiplexing gain and diversity gain, the spatial resolution of a large-scale MIMO system is significantly improved compared to a MIMO system in the related art. The large-scale MIMO system can deeply mine spatial dimension resources, so that multiple users within a coverage area of a base station can communicate with each other simultaneously on the same time-frequency resource by utilizing a degree of spatial freedom provided by the large-scale MIMO, and the large-scale MIMO system can also enhance a reuse capability of the spectrum resources among multiple terminals, thereby greatly improving a spectrum efficiency without increasing the density and bandwidth of the base station. For the high energy efficiency, the large-scale MIMO system can form narrower beams and concentrate radiation in a smaller spatial area, so that an energy efficiency on a radio frequency transmission link between the base station and a terminal can become higher and a transmission power loss of the base station can be reduced, which is an important technology for building future high-energy-efficient green broadband wireless communication systems. In regards to the high spatial resolution, the large-scale MIMO system have better robust performance. Since the number of antennas is much larger than the number of terminals, the system has a high degree of spatial freedom and a strong anti-interference capability. When the number of antennas at the base station tends to infinite, negative effects of additive white Gaussian noise and Rayleigh attenuation can all be ignored.

In order to better understand a CSI compression feedback method disclosed in embodiments of the disclosure, a communication system to which the embodiments of the disclosure is applied is first described below.

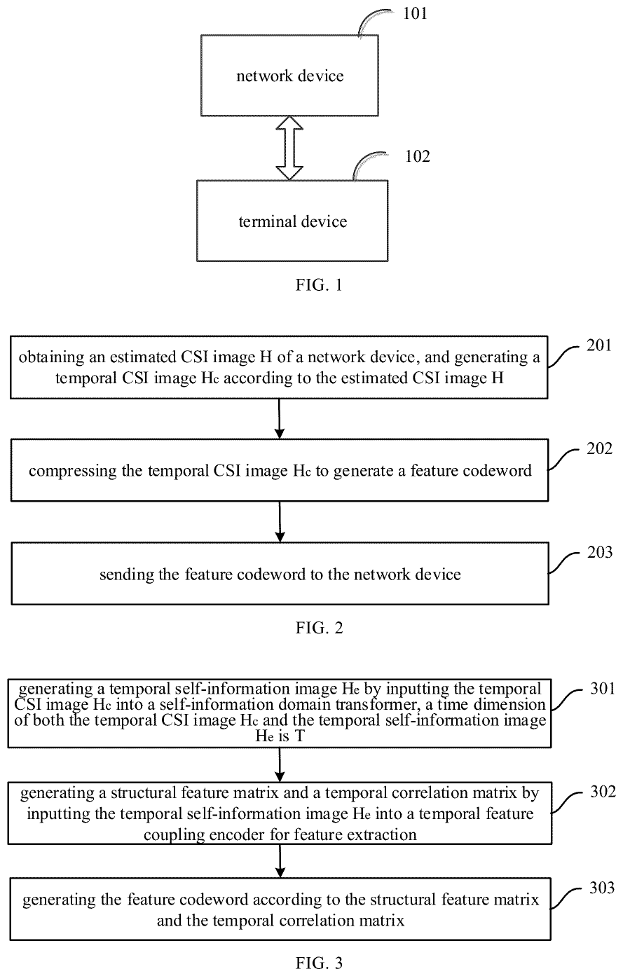

As illustrated in FIG. 1, FIG. 1 is a schematic diagram illustrating a communication system according to an embodiment of the disclosure. The communication system may include, but is not limited to, one network device and one terminal. The number and form of devices illustrated in FIG. 1 are only for examples and do not constitute a limitation on embodiments of the disclosure, and two or more network devices and two or more terminals may be included in practical applications. The communication system illustrated in FIG. 1 includes, for example, one network device 101 and one terminal 102.

It is noteworthy that technical solutions of embodiments of the disclosure can be performed by various communication systems, such as, a long term evolution (LTE) system, a 5G mobile communication system, a 5G NR system, or other future new mobile communication systems. It is also noted that the sidelink in embodiments of the disclosure may also be referred to as side link or direct link.

The network device 101 in embodiments of the disclosure is an entity on a network side for transmitting or receiving signals. For example, the network device 101 may be an evolved NodeB (eNB), a transmission reception point (TRP), a next generation NodeB (gNB) in a NR system, a base station in other future mobile communication systems, or an access node in a wireless fidelity (WiFi) system. The specific technology and specific device form adopted by the network device are not limited in embodiments of the disclosure. The network device according to embodiments of the disclosure may be composed of a central unit (CU) and distributed units (DUs). The CU may also be called a control unit. The use of the CU-DU structure allows to divide a protocol layer of the network device, such as a base station, such that some functions of the protocol layer are placed in the CU for centralized control, and some or all of the remaining functions of the protocol layer are distributed in the DUs, and the DUs are centrally controlled by the CU.

The terminal 102 in embodiments of the disclosure is an entity on a user side for receiving or transmitting signals, such as a cellular phone. The terminal may also be referred to as a terminal device, user equipment (UE), a mobile station (MS), a mobile terminal (MT), and the like. The terminal can be a car with a communication function, a smart car, a mobile phone, a wearable device, a Pad, a computer with a wireless transceiver function a virtual reality (VR) terminal, an augmented reality (AR) terminal, a wireless terminal in industrial control, a wireless terminal in self-driving, a wireless terminal in remote medical surgery, a wireless terminal in smart grid, a wireless terminal in transportation safety, a wireless terminal in smart city, a wireless terminal in smart home, etc. The specific technology and specific device form adopted by the terminal are not limited in embodiments of the disclosure.

With the development of 5G wireless communication networks, the mMIMO has become a key technology. By configuring a large number of antennas, the mMIMO not only greatly improves a channel capacity under limited spectrum resources, but also has a strong anti-interference capability. In order to better utilize the mMIMO technology, a transmitter may obtain CSI. In the system, a UE estimates CSI of a downlink channel and then feeds back the CSI to a base station (BS) through a feedback link with a fixed bandwidth. However, due to the multi-antenna nature of the mMIMO, an overhead of CSI feedback is huge, and thus how to efficiently and accurately feed back the CSI remains a severe challenge.

In order to reduce the overhead of feeding back the CSI, researchers have proposed many algorithms based on the compression estimation theory, and most of them use the spatial and temporal correlation of the channel to reduce the overhead. In traditional compression methods, a compressed sensing (CS)-based feedback method transforms a CSI matrix into a sparse matrix under a certain basis and uses a computer-based method for feedback. A quantization-based codebook compression method quantizes the CSI into a certain number of bits. With the rapid development of deep learning in recent years, deep learning has been widely used in fields such as computer vision, speech signal processing and natural language processing. Since deep learning networks have powerful capabilities such as parallel computing, adaptive learning, and cross-domain knowledge sharing, deep learning methods are gradually being used in the CSI compression feedback field to further reduce the CSI feedback overhead. For example, a deep learning network achieves the purpose of CSI feedback by treating MIMO channel data as image information, compressing CSI using an encoder, and finally restoring it using a decoder. An improved deep learning network performs CSI compression and feedback by utilizing the temporal correlation of the channel.

In the related art, the CSI feedback method based on the spatial correlation of the channel utilizes a related algorithm to divide channel elements with spatial correlation into several clusters, and maps multiple channel elements in each cluster into a single characterization value, and several grouping modes are divided depending on a cluster classification method. A selected grouping mode and characterization value are fed back to a transmitter through a feedback link for CSI reconstruction. However, this method requires strong spatial correlation among channel elements, and it cannot achieve accurate CSI compression and feedback for channels with very small spatial correlation. Moreover, the algorithm of this method is rather complicated, and as the number of antennas of the transmitter increases, the number of clusters increases, and thus the feedback overhead is still huge.

In the related art, a CSI matrix in a space-frequency domain is transformed into a CSI matrix in an angle domain through a two-dimensional discrete Fourier transformation (DFT). The real and imaginary portions of the CSI matrix are separated to obtain two-dimensional CSI image information. In the angle domain, due to the time delay of multipath arrival and the sparsity of the mMIMO channel information matrix, a main value portion of the CSI image is extracted. The extracted CSI matrix is used as an input of a deep learning network for training. An encoder is deployed on the UE side and used to compress the extracted CSI image into a low-dimensional codeword, and a decoder is deployed on the base station side and used to restore the compressed low-dimensional codeword into a corresponding CSI image to obtain a reconstructed channel. Finally, offline training and parameter update are performed on the deep learning network to make the reconstructed channel as close as possible to the original channel in the angle domain. Finally, an inverse two-dimensional DFT transformation is performed on the reconstructed channel to obtain the original CSI matrix in the spatial frequency domain. The trained deep learning network model can be applied to online deployment applications.

However, the above-mentioned deep learning-based CSI compression and feedback method only uses the original channel parameters for compression and feedback. For temporal CSI with temporal correlation, the original channel parameters cannot well reflect a structural characteristic and a temporal correlation characteristic of the temporal CSI. The above method only compresses the CSI from the perspective of image, and cannot accurately compress and reconstruct the CSI using the temporal correlation characteristic for the temporal CSI with temporal correlation. The multi-antenna nature of the mMIMO causes an overhead of CSI feedback to be huge, but there is lack of means for efficiently and accurately feeding back the CSI in the related art.

It can be understood that the communication system described in embodiments of the disclosure is intended to more clearly illustrate the technical solutions of embodiments of the disclosure, and does not constitute a limitation on the technical solutions provided in embodiments of the disclosure. Those skilled in the art may understand that as the system architecture evolves and new service scenarios emerge, the technical solutions according to embodiments of the disclosure are also applicable to similar technical problems.

The CSI compression feedback methods and the communication device provided in the disclosure are described in detail below in combination with the accompanying drawings.

As illustrated in FIG. 2, FIG. 2 is a flowchart of a CSI compression feedback method of an embodiment of the disclosure. The method can be applied to various communication systems, such as, a 5G mobile communication system, a 5G NR system, or other future new mobile communication systems. As illustrated in FIG. 2, the method is performed by a terminal. The method includes, but is not limited to the following steps.

At step 201, an estimated CSI image H of a network device is obtained, and a temporal CSI image H_{c} is generated according to the estimated CSI image H.

In embodiments of the disclosure, in the communication between the terminal and the network device, a signal is transmitted by means of Frequency Division Duplex (FDD), which utilizes a frequency division multiplexing technique to separately transmit and receive signals. The upload and download range are separated according to a frequency offset. In the FDD mMIMO downlink, i.e., a channel from the network device to the terminal, multiple antennas are deployed at the network device, and mMIMO transmission is performed using Orthogonal Frequency Division Multiplexing (OFDM) technology with multiple subcarriers on the channel. In order to better transmit signals and improve the performance of the mMIMO system, the network device as the transmitter of the downlink may obtain CSI. The CSI is obtained by the terminal through channel estimation, and a size of the estimated CSI image His T×c×Nₛ×Nₜ. In the disclosure, the CSI acquired by the terminal has temporal correlation, i.e., the CSI includes a time sequence. T represents a length of the time sequence, c represents a dimension of real and imaginary portions of the channel, and the channel has only one real portion and one imaginary portion, i.e., c=2. Nₛ represents a number of subcarriers, and Nₜ represents a number of antennas deployed at the network device.

The estimated CSI image H contains spatial domain information. In order to transform the estimated CSI image H to the angle domain, a two-dimensional DFT is performed on the estimated CSI image H, and the temporal CSI image H_{c} can be obtained after the transformation. The temporal CSI image H_{c} is more sparse compared to the estimated CSI image H. Due to the effect of the multipath delay, only the first Ne rows in the transformed estimated CSI image H have values, so that N_{c} is the number of valid rows and only data in the first N_{c} rows are reserved, thus the size of the temporal CSI image Hₑ is T×c×N_{c}×Nₜ.

In a possible embodiment, 32 (i.e., Nₜ=32) antennas spaced by half wavelength are configured in a way of a Uniform Linear Array (ULA) on the network device, and a single antenna is configured on the terminal. Using the COST2100 channel model, 150,000 space-frequency domain CSI matrix samples are generated in a 5.3 GHZ indoor microcellular scenario and divided into a training set containing 100,000 samples, a verification set containing 30,000 samples, and a test set containing 20,000 samples. The mMIMO system adopts the OFDM technique and there are 1024 subcarriers (i.e., Nₛ=1024), the CSI information matrix under the space-frequency domain is H=[\tilde{h}₁ . . . \tilde{h}_{N}_{ₛ}] #, and a length T of the time sequence of each CSI information matrix is set to T=5. In this case, the number of fed back parameters in each CSI information matrix is 1024×32, which is a huge overhead when the feedback bandwidth is limited.

To reduce the feedback overhead, the CSI information matrix H is transformed from the space-frequency domain to an angle delay domain using two-dimensional DFT, i.e., H_{c}=F_{d}HFₐ^{H}, in which F_{d} and Fₐ^{H} are discrete Fourier transform matrices with sizes of 1024×1024 and 32×32, respectively, and the superscript H represents a conjugate transpose of the matrix. In the angle delay domain, using the delay characteristic of multipath arrival in a limited time period, the first N_{c}=32 rows, i.e., the main value portion, of H_{c} is extracted, and the size of the temporal CSI image H_{c} in the angle domain is 5×2×32×32.

At step 202, the temporal CSI image Hₑ is compressed to generate a feature codeword.

In embodiments of the disclosure, the temporal CSI image H_{c} may be fed back to the network device. However, directly sending the temporal CSI image H_{c} may occupy excessive channel resources and cause resource waste. Thus the temporal CSI image H_{c} needs to be compressed and simplified to save resources. In embodiments of the disclosure, a self-information domain transformer projects the temporal CSI image into a self-information domain to obtain a temporal self-information image Hₑ. Due to the differences in information carried by various parts of a high-frequency channel image, by projecting the temporal CSI image into a self-information dimension, its structural feature and temporal correlation feature can be highlighted, and the temporal CSI image has a better compressibility in the self-information dimension.

The temporal self-information image Hₑ is input into a temporal feature coupling encoder to use a recurrent neural network (e.g., Long Short-Term Memory (LSTM)) to extract the temporal correlation information among the self-information images. Meanwhile, structural feature information of the channel image projected on the self-information domain is obtained by using a one-dimensional space compression network, and the extracted temporal correlation information and structural feature information are summed up and coupled to obtain the final feature codeword that is implicitly fed back.

At step 203, the feature codeword is sent to the network device.

In embodiments of the disclosure, the temporal CSI image H_{c} is compressed to obtain the feature codeword. The feature codeword contains information related to the temporal CSI image H_{c}. After the feature codeword is sent to the network device, the network device restores the feature codeword to obtain a restored temporal CSI image, and performs mMIMO transmission based on the restored CSI image.

By implementing the embodiments of the disclosure, the terminal compresses the temporal CSI image H_{c} corresponding to the estimated CSI image H to generates the feature codeword, and the temporal CSI image can be fed back to the network device through the feature codeword, which can reduce channel resources occupied for feeding back the CSI image, thereby saving resources and improving the accuracy of feeding back the CSI image.

As illustrated in FIG. 3, FIG. 3 is a flowchart of a CSI compression feedback method of an embodiment of the disclosure. The method can be applied to various communication systems, such as, a 5G mobile communication system, a 5G NR system, or other future new mobile communication systems. As illustrated in FIG. 3, the method includes, but is not limited to the following steps.

At step 301, a temporal self-information image Hₑ is generated by inputting the temporal CSI image H_{c} into a self-information domain transformer, in which a time dimension of both the temporal CSI image H_{c} and the temporal self-information image Hₑ is a time dimension of T.

In embodiments of the disclosure, the temporal CSI image H_{c} is projected into the self-information domain by the self-information domain transformer to obtain the temporal self-information image Hₑ. Due to differences in information carried by various parts of a high-frequency channel image, by projecting the temporal CSI image into the self-information dimension, its structural features and temporal correlation features can be highlighted, and the temporal CSI image in the self-information dimension has better compressibility.

At step 302, a structural feature matrix and a temporal correlation matrix are generated by inputting the temporal self-information image Hₑ into a temporal feature coupling encoder for feature extraction.

In embodiments of the disclosure, the structural feature and the temporal correlation feature of the temporal self-information image Hₑ are extracted by the temporal feature coupling encoder. The structural feature matrix includes the structural features, and the temporal correlation matrix includes the temporal correlation features.

At step 303, the feature codeword is generated according to the structural feature matrix and the temporal correlation matrix.

In embodiments of the disclosure, the structural feature matrix and the temporal correlation matrix are coupled to obtain the feature codeword.

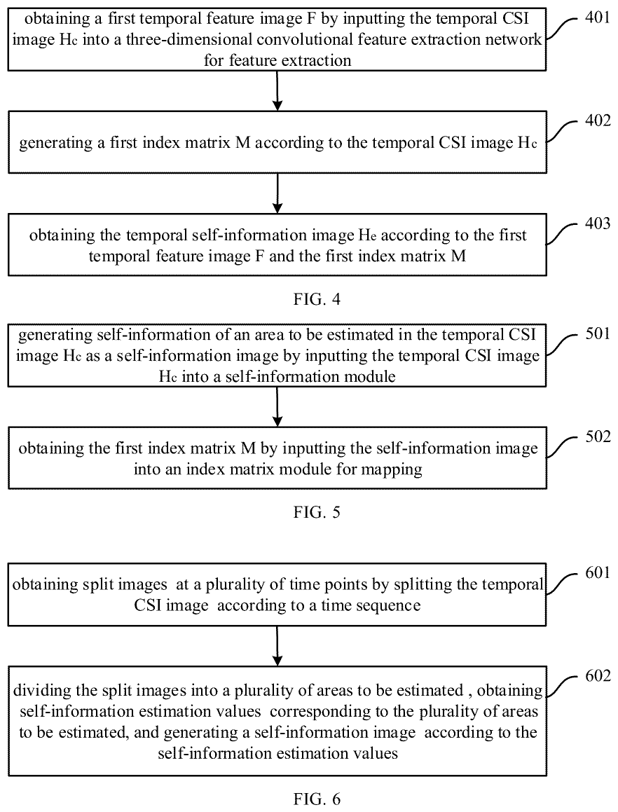

As illustrated in FIG. 4, FIG. 4 is a flowchart of a CSI compression feedback method of an embodiment of the disclosure. The method can be applied to various communication systems, such as, a 5G mobile communication system, a 5G NR system, or other future new mobile communication systems. As illustrated in FIG. 4, the method includes, but is not limited to the following steps.

At step 401a, a first temporal feature image F is obtained by inputting the temporal CSI image H_{c} into a three-dimensional convolutional feature extraction network for feature extraction, in which a convolution kernel specification of the three-dimensional convolutional network is f×t×n×n, f represents a number of features to be extracted, t represents a convolution depth in a time dimension, and n represents a length and a width of a convolution window.

In embodiments of the disclosure, the temporal CSI image H_{c} contains information of the time dimension, so that a two-dimensional convolutional layer is unable to effectively extract features in the image. In embodiments of the disclosure, a three-dimensional convolutional feature extraction network is used to extract features in the temporal CSI image. The three-dimensional convolutional network includes a convolutional layer, a three-dimensional normalization layer and an activation function layer. A convolutional kernel specification of the convolutional layer in the three-dimensional convolutional network is f×t×n×n, which means that the convolutional kernel extracts f features from the temporal CSI image H_{c} during each convolution. In order to prevent gradient disappearing or gradient exploding, an output of the convolutional layer is input into the three-dimensional normalization layer for normalization, and then input into the activation function layer to obtain the first temporal feature image F, F∈R^{T×f×N}^{_{c}}^{×N}^{ₜ}. An activation function of the activation function layer is a LeakyReLU activation function, and an equation of the LeakyReLU activation function is expressed as follows:

$$LeakyReLU ( x ) = \{ \begin{matrix}x , & x \geq 0 \\ 0.3 x , & x \leq 0\end{matrix} .$$

In a possible embodiment, the three-dimensional convolutional feature extraction network transforms the temporal CSI image H_{c} into a first temporal feature image FE R^{5×64×32×32}, where 64 features are extracted from each CSI image, which corresponding to a dimension of 64. Since the temporal CSI image contains a time dimension on which a two-dimensional convolutional layer is incapable of performing effective feature extraction, and thus in the disclosure, the feature extraction network uses a three-dimensional convolutional layer with a convolutional kernel whose size is 64×1×3×3.

At step 401b, a first index matrix M is generated according to the temporal CSI image H_{c}.

In embodiments of the disclosure, the temporal CSI image H_{c} may be input into a self-information module for extracting self-information when it is input into the three-dimensional convolutional feature extraction network. The self-information can be used to measure an amount of information contained when a single event occurs, and a self-information image is obtained according to the self-information. The self-information image is mapped through an index matrix module to obtain a second index matrix.

At step 402, the temporal self-information image Hₑ is obtained according to the first temporal feature image F and the first index matrix M.

In embodiments of the disclosure, after obtaining the first temporal feature image F and the first index matrix M, the first temporal feature image F and the first index matrix M are multiplied point-to-point to obtain an information feature image (i.e., the second information feature image) with information redundancy removed, and dimension restoration is performed on the second information feature image to generate the temporal self-information image Hₑ.

As illustrated in FIG. 5, FIG. 5 is a flowchart of a CSI compression feedback method of an embodiment of the disclosure. The method can be applied to various communication systems, such as, a 5G mobile communication system, a 5G NR system, or other future new mobile communication systems. As illustrated in FIG. 5, the method includes, but is not limited to the following steps.

At step 501, self-information of an area to be estimated in the temporal CSI image H_{c} is generated as a self-information image by inputting the temporal CSI image H_{c} into a self-information module.

In embodiments of the disclosure, the temporal CSI image H_{c} contains information of a time dimension, i.e., a time sequence. The self-information in the temporal CSI image H_{c} at each time point in the time sequence may be computed, and the self-information at each time point constitutes a corresponding self-information image.

At step 502, the first index matrix M is obtained by inputting the self-information image into an index matrix module for mapping.

In embodiments of the disclosure, after obtaining the self-information image, the self-information image is input into the index matrix module. The index matrix module includes: a mapping network, a judger and a splicing module. The mapping module maps the self-information image to a self-information domain to obtain a second index matrix. The second index matrixes correspond to the temporal CSI images H_{c} at respective time points in the time sequence respectively. In order to maintain the information of the time dimension, the second index matrixes may be spliced according to an order in the time sequence to obtain the first index matrix M.

As illustrated in FIG. 6, FIG. 6 is a flowchart of a CSI compression feedback method of an embodiment of the disclosure. The method can be applied to various communication systems, such as, a 5G mobile communication system, a 5G NR system, or other future new mobile communication systems. As illustrated in FIG. 6, the method includes, but is not limited to the following steps.

At step 601, split images H_{c,i} at a plurality of time points are obtained by splitting the temporal CSI image H_{c} according to a time sequence.

In embodiments of the disclosure, the temporal CSI image H_{c} contains information of a time dimension, i.e., the time sequence. The self-information in the temporal CSI image H_{c} at various time points in the time sequence may be calculated. The temporal CSI images H_{c} is split according to the time sequence to obtain the split images H_{c,i} at respective time points, H_{c,i}∈R^{c×N}^{_{c}}^{×N}^{ₜ}, i∈(1,2, . . . , T), there are T dimensions in the time sequence, so T split images H_{c,i} are obtained by the slitting.

At step 602, the split images are divided into a plurality of areas to be estimated pⱼ, self-information estimation values Îⱼ corresponding to the plurality of areas to be estimated are obtained, and a self-information image I_{c,i} is generated according to the self-information estimation values Îⱼ.

In embodiments of the disclosure, after obtaining the split images H_{c,i}, for each split image H_{c,i}, a real portion is represented by [symbol] (H_{c,i}), and an imaginary portion is represented by [symbol] (H_{c,i}). [symbol] (H_{c,i}) and [symbol] (H_{c,i}) are divided into a plurality of areas to be estimated using a window of a size of n×n, and each area to be estimated is represented by pⱼ∈R^{n×n}, j∈[1, 2, . . . , (N_{c}−n+1) (Nₜ−n+1)]. The self-information of each area pⱼ is calculated by the following equation:

$${\hat{I}}_{j} = - {log}_{2} \frac{1}{{( 2 R + 1 )}^{2}} {\sum }_{{p}_{j , r}^{′} ∈ {N}_{j}} \frac{1}{\sqrt{2 π} h} exp ( - {‖ {p}_{j} - {p}_{j , r}^{′} ‖}_{2}^{2} / 2 {h}^{2} ) + constant$$

where Îⱼ represents the self-information estimation value of pⱼ; Nⱼ represents a set containing all the areas adjacent to pⱼ; p_{j,r}′ is the r^{th} area adjacent to pⱼ; r=[1, 2, . . . , (2R+1)²]; R is the Manhattan radius, which is used for the determination of the boundary of Nⱼ; his the bandwidth, which is used to adjust the influence of the distance between pⱼ and p_{j,r}′ on calculating the self-information, and constant represents a constant value.

In a possible embodiment, the split CSI image is represented as H_{c,i}∈R^{2×32×32}, i=(1,2, . . . ,5). For each H_{c,i}, the real portion is represented by [symbol] (H_{c,i}) and the imaginary portion is represented by [symbol] (H_{c,i}). [symbol] (H_{c,i}) and [symbol] (H_{c,i}) are divided into a plurality of areas using a window of a size of 1×1, each area is represented by pⱼ∈R^{1×1}, j=[1,2, . . . ,1024]. In p_{j,r}′, r=[1,2, . . . ,49]. The Manhattan radius R=3, the bandwidth h=1, and the constant=3×10⁻⁶. In order to simplify the calculation, each pixel in H_{c,i} is taken as an area and its self-information is calculated, and all the self-information values Îⱼ constitute a matrix to obtain a self-information matrix I_{c,i} ∈R^{2×32×32} of H_{c,i}.

In a possible embodiment, to simplify the computation, each pixel in the Hoi is taken as an area for computing the self-information estimation value Îⱼ of the pⱼ.

All the self-information values Îⱼ form a matrix, to obtain a self-information image I_{c,i} ∈R^{c×N}^{_{c}}^{×N}^{ₜ} of the H_{c,i}.

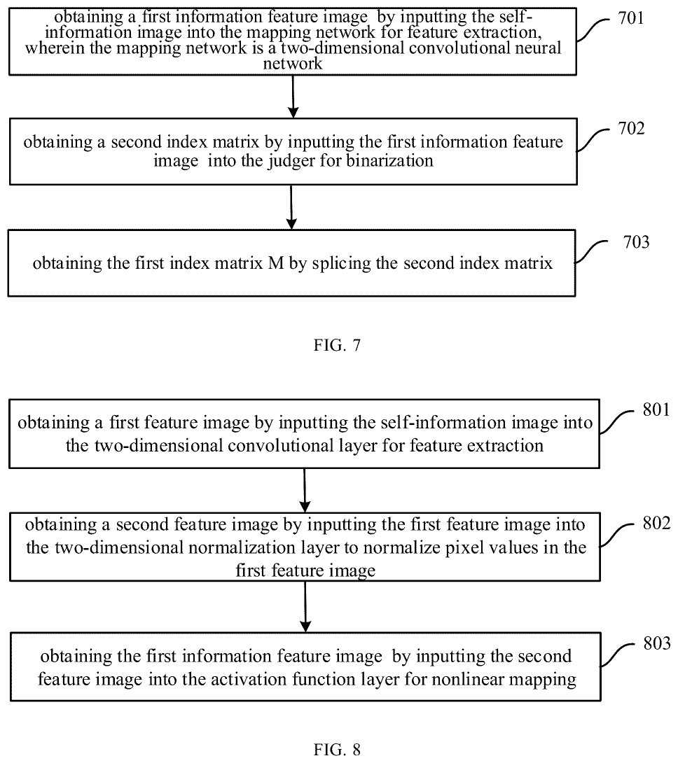

As illustrated in FIG. 7, FIG. 7 is a flowchart of a CSI compression feedback method of an embodiment of the disclosure. The method can be applied to various communication systems, such as, a 5G mobile communication system, a 5G NR system, or other future new mobile communication systems. As illustrated in FIG. 7, the method includes, but is not limited to the following steps.

At step 701, a first information feature image D_{c,i} is obtained by inputting the self-information image into a mapping network for feature extraction, in which the mapping network is a two-dimensional convolutional neural network.

In embodiments of the disclosure, the mapping network includes a two-dimensional convolutional layer, a two-dimensional normalization layer and an activation function layer. The self-information image contains information of only two dimensions, so the size of a convolution kernel in the two-dimensional convolutional layer is f×n×n. After extracting features through the two-dimensional convolutional layer, the features are input into the two-dimensional normalization layer to normalize feature values, and then input into the activation function layer to obtain the first information feature image D_{c,i}. The activation function of the activation function layer is a LeakyReLU activation function.

At step 702, a second index matrix Mᵢ is obtained by inputting the first information feature image D_{c,i} into a judger for binarization.

In embodiments of the disclosure, the judger performs binarization processing on the first information feature image D_{c,i} and sets a threshold Y. For an element value corresponding to each element in the first information feature image D_{c,i}, if the element value is greater than or equal to the threshold Y set by the judger, an element corresponding to the element value is set to 1. If the element value is less than the threshold Y set by the judger, the element corresponding to the element value is set to 0. Thus, the second index matrix Mᵢ is obtained, where Mᵢ∈R^{f×N}^{_{c}}^{×N}^{ₜ}.

In a possible embodiment, the threshold Y=9.288, the judger sets the elements in D_{c,i} whose values are less than 9.288 to 0, and the elements whose values are greater than 9.288 to 1, so that a final index matrix Mᵢ ∈R^{64×32×32} is obtained.

At step 703, the first index matrix M is obtained by splicing the second index matrix Mᵢ.

In embodiments of the disclosure, the split image H_{c,i} corresponding to the second index matrix Mᵢ is an image at a time point in the temporal CSI image H_{c}, so that the second index matrix Mᵢ can be spliced in the order of the time sequence to obtain the first index matrix M.

As illustrated in FIG. 8, FIG. 8 is a flowchart of a CSI compression feedback method of an embodiment of the disclosure. The method can be applied to various communication systems, such as, a 5G mobile communication system, a 5G NR system, or other future new mobile communication systems. As illustrated in FIG. 8, the mapping network includes a two-dimensional convolutional layer, a two-dimensional normalization layer and an activation layer, the method includes, but is not limited to the following steps.

At step 801, a first feature image is obtained by inputting the self-information image into the two-dimensional convolutional layer for feature extraction.

In embodiments of the disclosure, the self-information image contains information of only two dimensions, so a size of a convolution kernel in the two-dimensional convolutional layer is f×n×n. The features are extracted by the two-dimensional convolutional layer to obtain the first feature image.

At step 802, a second feature image is obtained by inputting the first feature image into the two-dimensional normalization layer to normalize pixel values in the first feature image.

In embodiments of the disclosure, in order to prevent gradient disappearance and gradient explosion, the first feature image is input into the two-dimensional normalization layer, so that the value of each pixel in the second feature image is normalized to keep the size of the pixel value within a range of 0 to 1.

At step 803, the first information feature image D_{c,i} is obtained by inputting the second feature image into the activation function layer for nonlinear mapping.

In embodiments of the disclosure, an activation function of the activation function layer is the LeakyReLU activation function.

In a possible embodiment, the mapping network maps I_{c,i} into an information feature image D_{c,i}=R^{64×32×32}, and a size of a convolution kernel of the two-dimensional convolutional layer in the mapping network is 64×3×3.

Optionally, obtaining the first index matrix M by splicing the second index matrix Mᵢ includes:

obtaining the first index matrix M by splicing the second index matrix Mᵢ in an order of a time sequence.

In embodiments of the disclosure, the split image H_{c,i} corresponding to the second index matrix Mᵢ is an image at a time point in the temporal CSI image H_{c}, so that the second index matrix Mᵢ can be spliced in the order of the time sequence to obtain the first index matrix M.

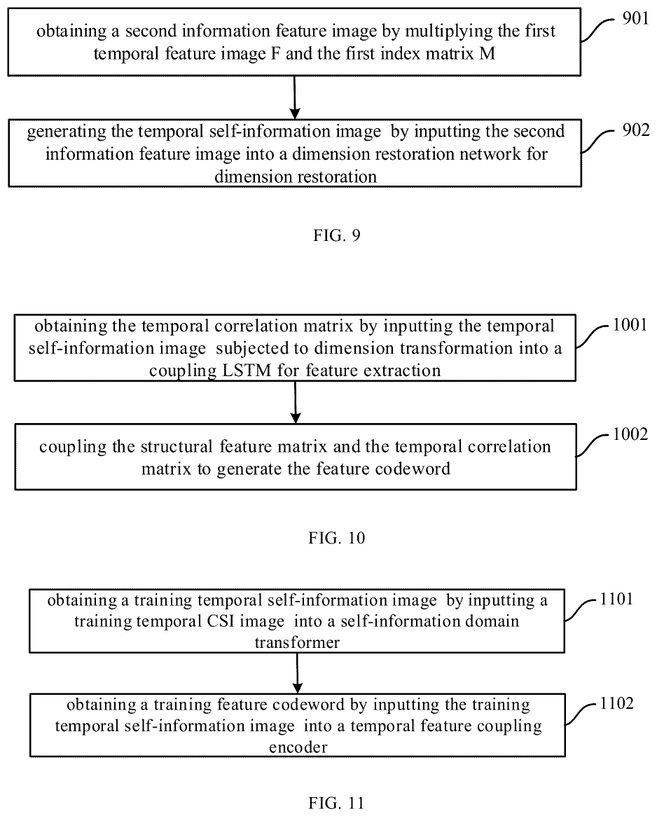

As illustrated in FIG. 9, FIG. 9 is a flowchart of a CSI compression feedback method of an embodiment of the disclosure. The method can be performed by various communication systems, such as, a 5G mobile communication system, a 5G NR system, or other future new mobile communication systems. As illustrated in FIG. 9, the method includes, but is not limited to the following steps.

At step 901, a second information feature image is obtained by multiplying the first temporal feature image F and the first index matrix M.

In embodiments of the disclosure, information redundancy is removed by the three-dimensional convolutional feature extraction network, the self-information module and the index matrix module, and the first temporal feature image F and the first index matrix M are obtained. The first temporal feature image F and the first index matrix M are multiplexed to obtain the second information feature image, and the information features in the second information feature image is refined and can better reflect the characteristics of the channel.

At step 902, the temporal self-information image Hₑ is obtained by inputting the second information feature image into a dimension restoration network for dimension restoration.

In embodiments of the disclosure, the dimension restoration network includes a three-dimensional convolutional layer, a three-dimensional normalization layer and an activation function layer. A size of a convolution kernel of the three-dimensional convolution layer is c×t×n×n, where c is a restored dimension size, and c is a dimension of the real and imaginary portions, so c=2; t is the depth of the convolution in the time dimension; and n×n is the specification of a convolution window, i.e., the length and width of the convolution window are both n. The three-dimensional normalization layer performs a normalization process on an output of the three-dimensional convolution layer, and the activation function of the activation layer is a LeakyReLU activation function. The dimension restoration network performs dimension restoration on the second information feature image to obtain the temporal self-information image Hₑ. The temporal self-information image Hₑ has more prominent structural features and temporal correlation features compared to the temporal CSI image H_{c}.

Optionally, the size of the convolution kernel of the three-dimensional convolutional layer in the dimension restoration network is 2×1×3×3.

Optionally, the temporal feature coupling encoder includes a one-dimensional time-space compression network and a coupling LSTM.

Optionally, generating the structural feature matrix and the temporal correlation matrix by inputting the temporal self-information image Hₑ into the temporal feature coupling encoder for feature extraction includes:
obtaining the structural feature matrix by inputting the temporal self-information image Hₑ subjected to dimension transformation into the one-dimensional time-space compression network for one-dimensional time-space compression, in which a convolution kernel specification of the one-dimensional time-space compression network is S×2N_{c}Nₜ×m, 2N_{c}Nₜ represents a length of a convolution window, m represents a width of the convolution window, S represents a target dimension, and a dimension of the structural feature matrix is T×S. S=cN_{c}Nₜ/σ, where σ is a compression ratio.

In a possible embodiment, a size of a convolution kernel of the one-dimensional convolutional layer in the one-dimensional time-space compression network is S×1. The one-dimensional time-space compression network compresses the temporal self-information image Hₑ into S-dimensional structural feature information according to the compression rate, where S=2048/σ.

In embodiments of the disclosure, in order to save channel resources, the terminal feeds back the temporal self-information image Hₑ to the network device in the form of the codeword. In order to transform the temporal self-information image Hₑ into a feature codeword, the temporal feature coupling encoder extracts structural features and temporal correlation features of the temporal self-information image Hₑ to generate the structural feature matrix and the temporal correlation matrix.

As illustrated in FIG. 10, FIG. 10 is a flowchart of a CSI compression feedback method of an embodiment of the disclosure. The method can be applied to various communication systems, such as, a 5G mobile communication system, a 5G NR system, or other future new mobile communication systems. As illustrated in FIG. 10, the method includes, but is not limited to the following steps.

At step 1001, the temporal correlation matrix by inputting the temporal self-information image Hₑ subjected to dimension transformation into a coupling LSTM for feature extraction, in which a dimension of the temporal correlation matrix is T×S.

In embodiments of the disclosure, dimension transformation is performed on the temporal self-information image Hₑ, it is input into the coupling LSTM. The LSTM contains a plurality of structural units suitable for processing and predicting important events with very long intervals and delays in the time sequence. The coupling LSTM extracts the temporal correlation features to generate the temporal correlation matrix. The dimension of the temporal correlation matrix is the same as the dimension of the structural feature matrix, which is T×S.

In a possible embodiment, the number of structural units in the LSTM is T, which is equal to the time dimension of the temporal self-information image Hₑ. The structural units are connected in series, and an output of one structural unit is input into a next structural unit.

At step 1002, the structural feature matrix and the temporal correlation matrix are coupled to generate the feature codeword.

In embodiments of the disclosure, the dimension of the structural feature matrix and the temporal correlation feature matrix is the same, and the values of corresponding points in the structural feature matrix and the temporal correlation feature matrix are added and coupled to generate the feature codeword.

As illustrated in FIG. 11, FIG. 11 is a flowchart of a CSI compression feedback method of an embodiment of the disclosure. The method can be applied to various communication systems, such as, a 5G mobile communication system, a 5G NR system, or other future new mobile communication systems. As illustrated in FIG. 11, the method includes, but is not limited to the following steps.

At step 1101, a training temporal self-information image Hₑ is obtained by inputting a training temporal CSI image H_{c} into a self-information domain transformer.

In embodiments of the disclosure, the self-information domain transformer and the temporal feature coupling encoder in the terminal may be trained by inputting the training temporal CSI image H_{c} into the self-information domain transformer to obtain the training temporal self-information image Hₑ.

At step 1102, a training feature codeword is obtained by inputting the training temporal self-information image Hₑ into a temporal feature coupling encoder.

In embodiments of the disclosure, the training temporal self-information image Hₑ is input into the temporal feature coupling encoder to obtain the training feature codeword. After preliminary training, network parameters of the self-information domain transformer and the temporal feature coupling encoder are obtained.

Optionally, the method further includes:
sending training data to the network device, in which the training data includes the training feature codeword, a time-sequence length of a temporal self-information image Hₑ, a dimension of the training feature codeword, and a training temporal CSI image H_{c}.

In embodiments of the disclosure, in order for the network device to successfully decode the information in the feature codeword, the training data may be send to the network device to adjust the network parameters of the decoupling module in the network device.

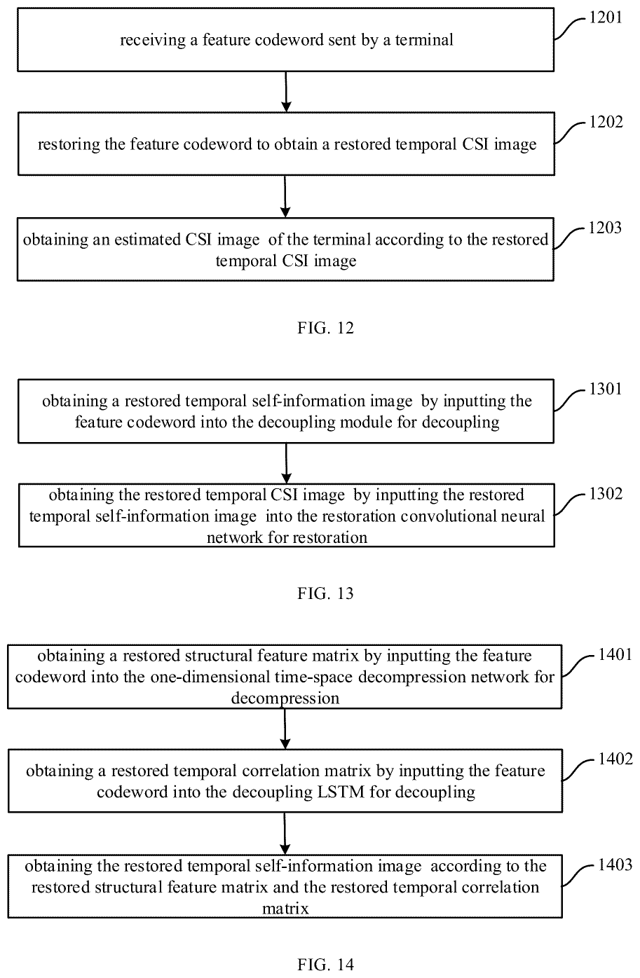

As illustrated in FIG. 12, FIG. 12 is a flowchart of a CSI compression feedback method of an embodiment of the disclosure. The method can be applied to various communication systems, such as, a 5G mobile communication system, a 5G NR system, or other future new mobile communication systems. As illustrated in FIG. 12, the method is performed by a network device, and the method includes, but is not limited to the following steps.

At step 1201, a feature codeword sent by a terminal is received.

In embodiments of the disclosure, the network device acts as a transmitter of downlink, and in order to better transmit signals and improve the performance of the mMIMO system, the network device may obtain CSI. A temporal CSI image is restored according to the feature codeword sent by the terminal.

At step 1202, the feature codeword is restored to obtain a restored temporal CSI image H_{c}.

In embodiments of the disclosure, the terminal restores the feature codeword by a decoupling module and a restoration convolutional neural network to obtain the restored temporal CSI image Ĥ_{c}. The decoupling module includes a one-dimensional time-space decompression network and a decoupling LSTM. The size of the restored temporal CSI image Ĥ_{c} is the same as the size of the temporal CSI image H_{c}, which is T×c×N_{c}×Nₜ.

At step 1203, an estimated CSI image Ĥ is obtained according to the restored temporal CSI image Ĥ_{c}.

In embodiments of the disclosure, a two-dimensional DFT inverse transform is performed on the restored temporal CSI image Ĥ_{c} to obtain the estimated CSI image Ĥ required by the network device.

By implementing embodiments of the disclosure, the network device decompresses the feature codeword compressed by the terminal to obtain the restored estimated CSI image Ĥ, which can reduce the channel resources occupied by feeding back CSI images, thereby saving resources and improving the accuracy of feeding back the CSI image.

Optionally, restoring the feature codeword, includes:
obtaining the restored temporal CSI image Ĥ_{c} by inputting the feature codeword into a temporal feature coupling decoder to obtain the restored temporal CSI image Ĥ_{c}.

As illustrated in FIG. 13, FIG. 13 is a flowchart of a CSI compression feedback method of an embodiment of the disclosure. The method can be applied to various communication systems, such as, a 5G mobile communication system, a 5G NR system, or other future new mobile communication systems. As illustrated in FIG. 13, the temporal feature decoupling decoder includes a decoupling module and a restoration convolutional neural network, the method includes, but is not limited to the following steps.

At step 1301, a restored temporal self-information image Ĥₑ is obtained by inputting the feature codeword into the decoupling module for decoupling.

In embodiments of the disclosure, the decoupling module includes a one-dimensional time-space decompression network and a decoupling LSTM. The decoupling module is structurally symmetric with the temporal feature coupling encoder of the network device. The one-dimensional time-space decompression network is used for extracting structural feature information in the feature codeword, and the decoupling LSTM is used for extracting temporal correlation information in the feature codeword.

At step 1302, the restored temporal CSI image Ĥ_{c} is obtained by inputting the restored temporal self-information image Ĥₑ into the restoration convolutional neural network for restoration.

In embodiments of the disclosure, the restoration convolutional neural network is used to restore a corresponding restored temporal CSI image Ĥ_{c} according to the restored temporal self-information image Ĥₑ.

As illustrated in FIG. 14, FIG. 14 is a flowchart of a CSI compression feedback method of an embodiment of the disclosure. The method can be applied to various communication systems, such as, a 5G mobile communication system, a 5G NR system, or other future new mobile communication systems. As illustrated in FIG. 14, the decoupling decoder includes a one-dimensional time-space decompression network and a decoupling LSTM, the method includes, but is not limited to the following steps.

At step 1401, a restored structural feature matrix is obtained by inputting the feature codeword into the one-dimensional time-space decompression network for decompression.

In embodiments of the disclosure, the one-dimensional time-space decompression network includes a one-dimensional convolutional layer, which contains a plurality of one-dimensional convolutional kernels.

At step 1402, a restored temporal correlation matrix is obtained by inputting the feature codeword into the decoupling LSTM for decoupling.

At step 1403, the restored temporal self-information image Ĥₑ is obtained according to the restored structural feature matrix and the restored temporal correlation matrix.

In embodiments of the disclosure, the dimension of the restored structural feature matrix and the restored temporal correlation matrix is the same, which is T×cN_{c}Nₜ. The restored structural feature matrix and the restored temporal correlation matrix are added point-to-point, and dimension transform is performed on the result of the adding to obtain the restored temporal self-information image Ĥₑ.

Optionally, the convolution kernel specification of the one-dimensional time-space decompression network is 2N_{c}Nₜ×S×m. The T is the number of rows of the restored temporal correlation matrix, and 2N_{c}Nₜ is the number of columns of the restored temporal correlation matrix.

Optionally, obtaining the restored temporal self-information image Ĥₑ according to the restored structural feature matrix and the restored temporal correlation matrix includes:
adding the restored structural feature matrix and the restored temporal correlation matrix point by point and performing dimension transformation to obtain the restored temporal self-information image Ĥₑ.

Optionally, the restored convolution neural network includes a first convolutional layer, a second convolutional layer, a third convolutional layer, a fourth convolutional layer, a fifth convolutional layer, a sixth convolutional layer, and a seventh convolutional layer. A convolution kernel specification of the first convolutional layer and the fourth convolutional layer is h×t×n×n, a convolution kernel specification of the second convolutional layer and the fifth convolutional layer is l₂×t×n×n, and a convolution kernel specification of the third convolutional layer, the sixth convolutional layer and the seventh convolutional layer is 2×t×n×n, t represents a convolution depth in a time dimension, l₁, l₂ and 2 are numbers of extracted features, and n represents a length and a width of a convolution window.

In a possible embodiment, the convolution kernel of the first convolution layer is 8×1×3×3, the convolution kernel of the second convolution layer is 16×1×3×3, the convolution kernel of the third convolution layer is 2×1×3×3, the convolution kernel of the fourth convolution layer is 8×1×3×3, the convolution kernel of the fifth convolution layer is 16×1×3×3, and the convolution kernel of the sixth convolution layer is 2×1×3×3. The step size of the first six three-dimensional convolution layers is 1, and the activation function adopts the LeakyReLU function. The seventh convolutional layer is a normalization layer with a convolution kernel of 2×1×3×3 and a step size of 1.

Optionally, obtaining the restored temporal CSI image Ĥ_{c} by inputting the restored temporal self-information image Ĥₑ into the restoration convolutional neural network for restoration includes:
obtaining a first restored feature map by inputting the restored temporal self-information image Ĥₑ into the first convolutional layer for convolution, obtaining a second restored feature map by inputting the first restored feature map into the second convolutional layer, obtaining a third restored feature map by inputting the second restored feature map into the third convolutional layer, and obtaining a fourth restored feature map by adding the third restored feature map with the restored temporal self-information image Ĥₑ;
obtaining a fifth restored feature map by inputting the fourth restored feature map into the fourth convolutional layer, obtaining a sixth restored feature map by inputting the fifth reduced feature map into the fifth convolutional layer, obtaining a seventh restored feature map by inputting the sixth restored feature map into the sixth convolutional layer, and obtaining an eighth restored feature map by adding the fourth restored feature map with the seventh restored feature map; and
obtaining the restored temporal CSI image Ĥ_{c} by inputting the eighth restored feature image into the seventh convolutional layer for normalization.

In embodiments of the disclosure, in order to prevent gradient disappearance during the training of the rebuilt CSI module, short-circuiting operations are performed on the first and fourth three-dimensional convolutional layers, and on the fourth and sixth three-dimensional convolutional layers. The step size of the first convolutional layer, the second convolutional layer, the third convolutional layer, the fourth convolutional layer, the fifth convolutional layer, and the sixth convolutional layer is k. The activation function of each convolutional layer is a Sigmoid function, and the equation of the Sigmoid function is:

$$S ( x ) = \frac{1}{1 + {e}^{- x}} .$$

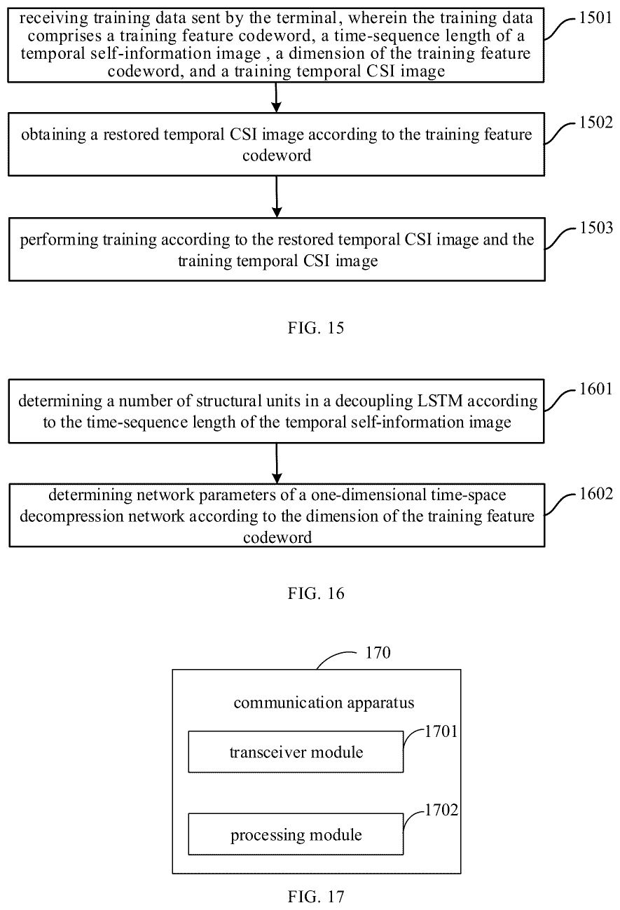

As illustrated in FIG. 15, FIG. 15 is a flowchart of a CSI compression feedback method of an embodiment of the disclosure. The method can be applied to various communication systems, such as, a 5G mobile communication system, a 5G NR system, or other future new mobile communication systems. As illustrated in FIG. 15, the method includes, but is not limited to the following steps.

At step 1501, training data sent by the terminal is received, in which the training data includes a training feature codeword, a time-sequence length of a temporal self-information image Hₑ, a dimension of the training feature codeword, and a training temporal CSI image.

In embodiments of the disclosure, the decoupling module and the restoration convolutional neural network in the temporal feature decoupling decoder deployed by the terminal may be trained. Training is performed according to the training data sent by the terminal.

At step 1502, a restored temporal CSI image is obtained according to the training feature codeword.

In embodiments of the disclosure, the training feature codeword is input into the temporal feature decoupling decoder for restoration to obtain the restored CSI image.

At step 1503, training is performed according to the restored temporal CSI image and the training temporal CSI image.

In embodiments of the disclosure, the network parameters in the temporal feature decoupling decoder may be optimized to make the restored temporal CSI image and the training temporal CSI image as close as possible.

As illustrated in FIG. 16, FIG. 16 is a flowchart of a CSI compression feedback method of an embodiment of the disclosure. The method can be applied to various communication systems, such as, a 5G mobile communication system, a 5G NR system, or other future new mobile communication systems. As illustrated in FIG. 16, the method includes, but is not limited to the following steps.

At step 1601, a number of structural units in the decoupling LSTM is determined according to a time-sequence length of the temporal self-information image Hₑ.

In embodiments of the disclosure, in order to enhance the effect of decoupling, the structure of the decoupling LSTM may be symmetrical with the structure of the coupling LSTM. The number of structural units in the coupling LSTM is T, which is the same as the length of the time sequence of the temporal self-information image Hₑ, so the number of structural units in the decoupling LSTM may be equal to T. The structural units in the decoupling LSTM are connected in series.

At step 1602, network parameters of the one-dimensional time-space decompression network is determined according to the dimension of the training feature codeword.

In embodiments of the disclosure, the structure of the one-dimensional time-space decompression network is the same as the structure of the one-dimensional time-space compression network. The number of features extracted by the one-dimensional time-space compression network is S, and thus the number of features decompressed by the one-dimensional time-space decompression network is also S. The dimension of the training feature codeword is T×S, and the size of the one-dimensional convolution kernel in the one-dimensional time-space decompression network is 2N_{c}Nₜ×S×m.

Optionally, the method includes:
performing multiple rounds of training, in which an equation of a learning rate in the training is represented as:

$$γ = {γ}_{min} + \frac{1}{2} ( {γ}_{max} + {γ}_{min} ) [ 1 + cos ( \frac{t - {T}_{w}}{{T}^{′} - {T}_{w}} π ) ] ,$$

where γ represents a current learning rate, γₘₐₓ represents a maximum learning rate, γₘᵢₙ represents a minimum learning rate, t represents a current number of training rounds, T_{w} represents a number of gradual learnings, T′ represents a number of overall training cycles.

In embodiments of the disclosure, during the training process, in order for the network to learn a global optimal solution, the learning rate of the network adopts the “asymptotic learning” method, in which the learning rate grows linearly in the first few training cycles, and then after reaching the peak, the learning rate decreases slowly in a cosine trend. The decreasing trend is as shown in the above expression of the equation of the learning rate.

In a possible embodiment, the learning rate grows linearly in the first 30 learning cycles, and after reaching the peak, the learning rate slowly decreases in a cosine trend, where γₘₐₓ=2×10⁻³, γₘᵢₙ=5×10⁻⁵, T_{w}=30, T′=2000.

Optionally, the method includes:
obtaining recommended network parameters for the decoupling module and the restored convolutional neural network, and updating the decoupling module and the restored convolutional neural network according to the recommended network parameters.

In embodiments of the disclosure, after the training is completed, the recommended network parameters of the decoupling module and the restoration convolutional neural network can be obtained, and the decoupling module and the restoration convolutional neural network can be updated according to the recommended network parameters.

In a possible embodiment, the self-information domain transformer of the terminal is used to generate the temporal self-information image Hₑ. The temporal self-information image Hₑ is input into the temporal feature coupling encoder to generate the feature codeword. The temporal feature coupling decoder in the network device is used to restore the feature codeword to a restored temporal CSI image Ĥ_{c}. The restored estimated CSI image Ĥ is obtained by performing a 2D DFT inverse transformation on the Ĥ_{c}. The network parameters are continuously updated during the transmission of the feature codeword.

Optionally, the method further includes followings. After the terminal obtains the feature codeword through the temporal feature coupling encoder, e-bit quantization is performed on the codeword for ease of transmission before being fed back to the network device. By using the trained network parameters, the restored temporal CSI image Ĥₑ is obtained after inverse quantization is performed and the temporal feature decoupling decoding by the network device. Optionally, 64-bit quantization is performed on the codeword before feeding back to the network device.

In the above-described embodiments provided in the disclosure, the method provided in embodiments of the disclosure is described from the perspective of a network device and a terminal, respectively. In order to realize each of the above-described functions in the method provided by embodiments of the disclosure, the network device and the terminal may include a hardware structure and/or a software module, and realize each of the above-described functions in the form of a hardware structure, a software module, or a combination of the hardware structure and the software module. A certain function of the above-described functions may be performed in the form of a hardware structure, a software module, or a combination of the hardware structure and the software module.

According to embodiments of the disclosure, a communication device is provided. The communication device has an ability to implement part or all of the functions of the terminal in the method described in the above embodiments. For example, the communication device may have functions of some or all of embodiments of the disclosure, or may have a function of independently implementing any embodiment of the disclosure. The functions can be implemented by hardware, or can be implemented by executing corresponding software using the hardware. The hardware or software includes one or more units or modules corresponding to the above functions.

In an implementation, the communication device includes: a transceiver module and a processing module. The processing module is configured to support the communication device to perform corresponding functions in the above method. The transceiver module is configured to support communication between the communication device and other devices. The communication device may further include a storage module coupled to the transceiver module and the processing module, and the storage module is configured to store necessary computer programs and data for the communication device.

As an example, the processing module may be a processor. The transceiver module may be a transceiver or a communication interface. The storage module may be a memory.

FIG. 17 is a schematic diagram of a communication device 170 provided by an embodiment of the disclosure. The communication device 170 shown in FIG. 17 may include a transceiver module 1701 and a processing module 1702. The transceiver module 1701 may include a transmitting module and/or a receiving module, the transmitting module is used to implement a transmitting function, and the receiving module is used to implement a receiving function. The transceiver module 1701 may implement a transmitting function and/or a receiving function.

The communication device 170 may be a terminal (e.g., the terminal in the above method embodiments), a device in the terminal, or a device capable of being used together with the terminal. Alternatively, the communication device 170 may be a network device, a device in the network device, or a device capable of being used together with the network device.

When implemented as a terminal, the communication device 170 includes:
an estimation module, configured to obtain an estimated CSI image H of a network device, and generate a temporal CSI image H_{c} according to the estimated CSI image H;
a compressing module, configured to compress the temporal CSI image H_{c} to generate a feature codeword; and
a sending module, configured to send the feature codeword to the network device.

When implemented as a network device, the communication device 170 includes:
a receiving module, configured to receive a feature codeword sent by a terminal;
a restoring module, configured to restore the feature codeword to obtain a restored temporal CSI image H_{c}; and
a channel obtaining module, configured to obtain a restored estimated CSI image Ĥ according to the restored temporal CSI image Ĥ_{c}.

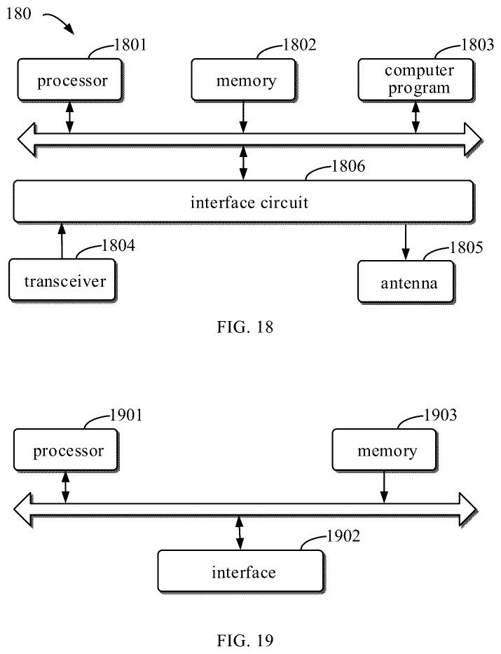

As illustrated in FIG. 18, FIG. 18 is a schematic diagram illustrating a communication device 180 according to an embodiment of the disclosure. The communication device 180 may be a network device, a terminal (e.g., the terminal according to the above method embodiments), or a chip, a chip system or a processor that supports the network device to realize the above-described methods, or a chip, a chip system or a processor that supports the terminal to realize the above-described methods. The device may be used to realize the methods described in the above method embodiments with reference to the descriptions of the above-described method embodiments.

The communication device 180 may include one or more processors 1801. The processor 1801 may be a general purpose processor or a dedicated processor, such as, a baseband processor or a central processor. The baseband processor is used for processing communication protocols and communication data. The central processor is used for controlling the communication device (e.g., base station, baseband chip, terminal, terminal chip, DU, or CU), executing computer programs, and processing data of the computer programs.

Optionally, the communication device 180 may include one or more memories 1802 on which computer programs 1804 may be stored. The processor 1801 executes the computer programs 1804 to cause the communication device 180 to perform the methods described in the above method embodiments. Optionally, data may also be stored in the memory 1802. The communication device 180 and the memory 1802 may be provided separately or may be integrated together.

Optionally, the communication device 180 may also include a transceiver 1805 and an antenna 1806. The transceiver 1805 may be referred to as transceiver unit, transceiver machine, or transceiver circuit, for realizing the transceiver function. The transceiver 1805 may include a receiver and a transmitter. The receiver may be referred to as receiver machine or receiving circuit, for realizing the receiving function. The transmitter may be referred to as transmitter machine or transmitting circuit, for realizing the transmitting function.

Optionally, the communication device 180 may also include one or more interface circuits 1807. The interface circuits 1807 are used to receive code instructions and transmit them to the processor 1801. The processor 1801 runs the code instructions to cause the communication device 180 to perform the method described in the method embodiments.

In an implementation, the processor 1801 may include a transceiver for implementing the receiving and transmitting functions. The transceiver may be, for example, a transceiver circuit, an interface, or an interface circuit. The transceiver circuit, interface, or interface circuit for implementing the receiving and transmitting functions may be separated or may be integrated together. The transceiver circuit, interface, or interface circuit described above may be used for code/data reading and writing, or may be used for signal transmission or delivery.

In an implementation, the processor 1801 may store a computer program 1803, which runs on the processor 1801 and may cause the communication device 180 to perform the methods described in the method embodiments above. The computer program 1803 may be solidified in the processor 1801, in which case the processor 1801 may be implemented by hardware.

In an implementation, the communication device 180 may include circuits. The circuits may implement the sending, receiving or communicating function in the preceding method embodiments. The processors and transceivers described in this disclosure may be implemented on integrated circuits (ICs), analog ICs, radio frequency integrated circuits (RFICs), mixed signal ICs, application specific integrated circuits (ASICs), printed circuit boards (PCBs), and electronic devices. The processors and transceivers can also be produced using various IC process technologies such as complementary metal oxide semiconductor (CMOS), nMetal-oxide-semiconductor (NMOS), positive channel metal oxide semiconductor (PMOS), bipolar junction transistor (BJT), bipolar CMOS (BiCMOS), silicon-germanium (SiGe), gallium arsenide (GaAs) and so on.

The communication device in the above description of embodiments may be a network device or a terminal (e.g., the terminal in the above method embodiments), but the scope of the communication device described in the disclosure is not limited thereto, and the structure of the communication device may not be limited by FIG. 18. The communication device may be a stand-alone device or may be part of a larger device. For example, the described communication device may be:
(1) a stand-alone IC, chip, chip system or subsystem;
(2) a collection of ICs including one or more ICs, optionally, the collection of ICs may also include storage components for storing data and computer programs;
(3) an ASIC, such as a modem;
(4) modules that can be embedded within other devices;
(5) receivers, terminals, smart terminals, cellular phones, wireless devices, handheld machines, mobile units, in-vehicle devices, network devices, cloud devices, artificial intelligence devices, and the like; and
(6) others.

The case where the communication device may be a chip or a chip system is described with reference to the schematic structure of the chip shown in FIG. 19. The chip shown in FIG. 19 includes a processor 1901 and an interface 1902. There may be one or more processors 1901, and there may be multiple interfaces 1902.

Optionally, the chip further includes a memory 1903 used for storing necessary computer programs and data.

It is understandable by those skilled in the art that various illustrative logical blocks and steps listed in embodiments of the disclosure may be implemented by electronic hardware, computer software, or a combination of both. Whether such function is implemented by hardware or software depends on the particular application and the design requirements of the entire system. Those skilled in the art may, for each particular application, use various methods to implement the described function, but such implementation should not be construed as being beyond the scope of protection of embodiments of the disclosure.

Embodiments of the disclosure also provide a CSI compression feedback system. The system includes a communication device as a terminal (e.g., the terminal in the above method embodiments) and a communication device as a network device in the preceding embodiment of FIG. 17. Or, the system includes a communication device as a terminal (e.g., the terminal in the above method embodiments) and a communication device as a network device in the preceding embodiment of FIG. 18.

The disclosure also provides a communicating device. The communicating device includes: a processor. When the processor calls a computer program stored in a memory, the method described in the above embodiments.

The disclosure also provides a communication device. The communication device includes: a processor and an interface circuit. The interface circuit is configured to receive code instructions and transmit them to the processor. The processor is configured to run the code instructions to cause the communication device to perform the method described in the above embodiments.

The disclosure also provides a chip system. The chip system includes at least one processor and an interface, for supporting the terminal in realizing the functions involved in the above embodiments, e.g., determining or processing at least one of data or information involved in the method described above. In a possible design, the chip system further includes a memory. The memory is configured to store necessary computer programs and data of the terminal. The chip system may consist of chips or may include a chip and other discrete devices.

The disclosure also provides a computer program. When the computer program is running on a computer, the computer is caused to implement the method of the first aspect.

The disclosure also provides a computer-readable storage medium having instructions stored thereon. When the instructions are executed by a computer, the function of any of the method embodiments described above is implemented.

The disclosure also provides a computer program product. When the computer program product is executed by a computer, the function of any of the method embodiments described above is implemented.

The above embodiments may be implemented in whole or in part by software, hardware, firmware, or any combination thereof. When implemented using software, it may be implemented, in whole or in part, in the form of a computer program product. The computer program product includes one or more computer programs. When loading and executing the computer program on the computer, all or part of processes or functions described in embodiments of the disclosure is implemented. The computer may be a general-purpose computer, a dedicated computer, a computer network, or other programmable devices. The computer program may be stored in a computer-readable storage medium or transmitted from one computer-readable storage medium to another computer-readable storage medium. For example, the computer program may be transmitted from one web site, computer, server, or data center to another web site, computer, server, or data center, in a wired manner (e.g., by using coaxial cables, fiber optics, or digital subscriber lines (DSLs) or wirelessly (e.g., by using infrared wave, wireless wave, or microwave). The computer-readable storage medium may be any usable medium to which the computer has access to or a data storage device such as a server and a data center integrated by one or more usable mediums. The usable medium may be a magnetic medium (e.g., floppy disk, hard disk, and tape), an optical medium (e.g., a high-density digital video disc (DVD)), or a semiconductor medium (e.g., a solid state disk (SSD)).

Those skilled in the art may understand that “first”, “second” and other various numerical numbers involved in the disclosure are only described for the convenience of differentiation, and are not used to limit the scope of embodiments of the disclosure, or used to indicate the order of precedence.

The term “at least one” in the disclosure may also be described as one or more, and the term “multiple” may be two, three, four, or more, which is not limited in the disclosure. In embodiments of the disclosure, for a type of technical features, “first”, “second”, and “third”, and “A”, “B”, “C” and “D” are used to distinguish different technical features of the type, the technical features described using the “first”, “second”, and “third”, and “A”, “B”, “C” and “D” do not indicate any order of precedence or magnitude.

The correspondences shown in the tables in this disclosure may be configured or may be predefined. The values of information in the tables are merely examples and may be configured to other values, which are not limited by the disclosure. In configuring the correspondence between the information and the parameter, it is not necessarily required that all the correspondences illustrated in the tables must be configured. For example, the correspondences illustrated in certain rows in the tables in this disclosure may not be configured. For another example, the above tables may be adjusted appropriately, such as splitting, combining, and the like. The names of the parameters shown in the titles of the above tables may be other names that can be understood by the communication device, and the values or representations of the parameters may be other values or representations that can be understood by the communication device. Each of the above tables may also be implemented with other data structures, such as, arrays, queues, containers, stacks, linear tables, pointers, chained lists, trees, graphs, structures, classes, heaps, and Hash tables.

The term “predefine” in this disclosure may be understood as define, define in advance, store, pre-store, pre-negotiate, pre-configure, solidify, or pre-fire.

Those skilled in the art may realize that the units and algorithmic steps of the various examples described in combination with embodiments disclosed herein are capable of being implemented in the form of electronic hardware, or a combination of computer software and electronic hardware. Whether these functions are performed in the form of hardware or software depends on the specific application and design constraints of the technical solution. Those skilled in the art may use different methods to implement the described functions for each particular application, but such implementations should not be considered as beyond the scope of the disclosure.

It is clearly understood by those skilled in the field to which it belongs that, for the convenience and brevity of description, the specific working processes of the systems, apparatuses, and units described above can be referred to the corresponding processes in the preceding method embodiments, and will not be repeated herein.

It will be appreciated that the disclosure is not limited to the exact construction that has been described above and illustrated in the accompanying drawings, and that various modifications and changes can be made without departing from the scope thereof. It is intended that the scope of the disclosure only be limited by the appended claims.

1. A channel state information (CSI) compression feedback method,
performed by a terminal, comprising:
obtaining an estimated CSI image H of a network device, and generating a temporal CSI image H_{c} according to the estimated CSI image H;
compressing the temporal CSI image H_{c} to generate a feature codeword; and
sending the feature codeword to the network device.

2. The method of claim 1, wherein compressing the temporal CSI image H_{c} to generate the feature codeword comprises:
generating a temporal self-information image Hₑ by inputting the temporal CSI image H_{c} into a self-information domain transformer, wherein a time dimension of both the temporal CSI image H_{c} and the temporal self-information image Hₑ is T;
generating a structural feature matrix and a temporal correlation matrix by inputting the temporal self-information image Hₑ into a temporal feature coupling encoder for feature extraction; and
generating the feature codeword according to the structural feature matrix and the temporal correlation matrix.

3. The method of claim 2, wherein generating the temporal self-information image Hₑ by inputting the temporal CSI image H_{c} into the self-information domain transformer comprises:
obtaining a first temporal feature image F by inputting the temporal CSI image H_{c} into a three-dimensional convolutional feature extraction network for feature extraction, wherein a convolution kernel specification of the three-dimensional convolutional network is f×t×n×n, f represents a number of features to be extracted, t represents a convolution depth in a time dimension, and n represents a length and a width of a convolution window;
generating a first index matrix M according to the temporal CSI image H_{c}; and
obtaining the temporal self-information image Hₑ according to the first temporal feature image F and the first index matrix M.

4. The method of claim 3, wherein generating the first index matrix M according to the temporal CSI image H_{c} comprises:
generating self-information of an area to be estimated in the temporal CSI image H_{c} as a self-information image by inputting the temporal CSI image H_{c} into a self-information module; and
obtaining the first index matrix M by inputting the self-information image into an index matrix module for mapping.

5. The method of claim 4, wherein generating the self-information of the area to be estimated in the temporal CSI image H_{c} as the self-information image by inputting the temporal CSI image Hₑ into a self-information module comprises:
obtaining split images H_{c,i} at a plurality of time points by splitting the temporal CSI image H_{c} according to a time sequence; and
dividing the split images into a plurality of areas to be estimated pⱼ, obtaining self-information estimation values Îⱼ corresponding to the plurality of areas to be estimated, and generating a self-information image I_{c,i} according to the self-information estimation values Îⱼ.

6. The method of claim 4, wherein the index matrix module comprises a mapping network and a judger, and obtaining the first index matrix M by inputting the self-information image into the index matrix module for mapping comprises:
obtaining a first information feature image D_{c,i} by inputting the self-information image into the mapping network for feature extraction, wherein the mapping network is a two-dimensional convolutional neural network;
obtaining a second index matrix Mᵢ by inputting the first information feature image D_{c,i} into the judger for binarization; and
obtaining the first index matrix M by splicing the second index matrix Mᵢ.

7. The method of claim 6, wherein the mapping network comprises a two-dimensional convolutional layer, a two-dimensional normalization layer and an activation function layer, and inputting the self-information image into the mapping network for feature extraction comprises:
obtaining a first feature image by inputting the self-information image into the two-dimensional convolutional layer for feature extraction;
obtaining a second feature image by inputting the first feature image into the two-dimensional normalization layer to normalize pixel values in the first feature image; and
obtaining the first information feature image D_{c,i} by inputting the second feature image into the activation function layer for nonlinear mapping;
or obtaining the first index matrix M by splicing the second index matrix Mᵢ comprises:
obtaining the first index matrix M by splicing the second index matrix Mᵢ in an order of a time sequence.

8. (canceled)

9. The method of claim 3, wherein obtaining the temporal self-information image Hₑ according to the first temporal feature image F and the first index matrix M comprises:
obtaining a second information feature image by multiplying the first temporal feature image F and the first index matrix M; and
generating the temporal self-information image Hₑ by inputting the second information feature image into a dimension restoration network for dimension restoration.

10. The method of claim 2, wherein the temporal feature coupling encoder comprises a one-dimensional time-space compression network and a coupling long short term memory network (LSTM).

11. The method of claim 10, wherein generating the structural feature matrix and the temporal correlation matrix by inputting the temporal self-information image Hₑ into the temporal feature coupling encoder for feature extraction comprises:
obtaining the structural feature matrix by inputting the temporal self-information image Hₑ subjected to dimension transformation into the one-dimensional time-space compression network for one-dimensional time-space compression, wherein a convolution kernel specification of the one-dimensional time-space compression network is S×2N_{c}Nₜ×m, 2N_{c}Nₜ represents a length of a convolution window, m represents a width of the convolution window, S represents a target dimension, and a dimension of the structural feature matrix is T×S; or
obtaining the temporal correlation matrix by inputting the temporal self-information image Hₑ subjected to dimension transformation into a coupling LSTM for feature extraction, wherein a dimension of the temporal correlation matrix is T×S; and coupling the structural feature matrix and the temporal correlation matrix to generate the feature codeword.

12. (canceled)

13. The method of claim 1, further comprising:
obtaining a training temporal self-information image Hₑ by inputting a training temporal CSI image H_{c} into a self-information domain transformer; and
obtaining a training feature codeword by inputting the training temporal self-information image Hₑ into a temporal feature coupling encoder;
sending training data to the network device, wherein the training data comprises the training feature codeword, a time-sequence length of a temporal self-information image Hₑ, a dimension of the training feature codeword, and a training temporal CSI image H_{c}.

14. (canceled)

15. A channel state information (CSI) compression feedback method, performed by a network device, comprising:
receiving a feature codeword sent by a terminal;
restoring the feature codeword to obtain a restored temporal CSI image H_{c}; and
obtaining an estimated CSI image Ĥ of the terminal according to the restored temporal CSI image Ĥ_{c}.

16. The method of claim 15, wherein restoring the feature codeword comprises:
obtaining the restored temporal CSI image Ĥ_{c} by inputting the feature codeword into a temporal feature coupling decoder.

17. The method of claim 16, wherein the temporal feature coupling decoder comprises a decoupling module and a restoration convolutional neural network, obtaining the restored temporal CSI image Ĥ_{c} comprises:
obtaining a restored temporal self-information image Ĥₑ by inputting the feature codeword into the decoupling module for decoupling; and
obtaining the restored temporal CSI image Ĥ_{c} by inputting the restored temporal self-information image Ĥₑ into the restoration convolutional neural network for restoration.

18. The method of claim 17, wherein the decoupling module comprises a one-dimensional time-space decompression network and a decoupling long short term memory network (LSTM), obtaining the restored temporal self-information image by inputting the feature codeword into the decoupling module for decoupling comprises:
obtaining a restored structural feature matrix by inputting the feature codeword into the one-dimensional time-space decompression network for decompression;
obtaining a restored temporal correlation matrix by inputting the feature codeword into the decoupling LSTM for decoupling; and
obtaining the restored temporal self-information image Ĥₑ according to the restored structural feature matrix and the restored temporal correlation matrix.

19. The method of claim 18, wherein a convolution kernel specification of the one-dimensional time-space decompression network is 2N_{c}Nₜ×S×m, 2N_{c}Nₜ represents a length of a convolution window, m represents a width of the convolution window, S represents a target dimension, and a dimension of the structural feature matrix is T×S;
wherein obtaining the restored temporal self-information image Ĥₑ according to the restored structural feature matrix and the restored temporal correlation matrix comprises:
adding the restored structural feature matrix and the restored temporal correlation matrix point by point and performing dimension transformation, to obtain the restored temporal self-information image Ĥₑ.

20. (canceled)

21. The method of claim 17, wherein the restored convolution neural network comprises a first convolutional layer, a second convolutional layer, a third convolutional layer, a fourth convolutional layer, a fifth convolutional layer, a sixth convolutional layer, and a seventh convolutional layer, wherein a convolution kernel specification of the first convolutional layer and the fourth convolutional layer is l₁×t×n×n, a convolution kernel specification of the second convolutional layer and the fifth convolutional layer is l₂×t×n×n, and a convolution kernel specification of the third convolutional layer, the sixth convolutional layer and the seventh convolutional layer is 2×t×n×n, t represents a convolution depth in a time dimension, l₁, l₂ and 2 are numbers of extracted features, and n represents a length and a width of a convolution window;
wherein obtaining the restored temporal CSI image Ĥ_{c} by inputting the restored temporal self-information image Ĥₑ into the restoration convolutional neural network for restoration comprises:
obtaining a first restored feature map by inputting the restored temporal self-information image Ĥₑ into the first convolutional layer for convolution, obtaining a second restored feature map by inputting the first restored feature map into the second convolutional layer, obtaining a third restored feature map by inputting the second restored feature map into the third convolutional layer, and obtaining a fourth restored feature map by adding the third restored feature map and the restored temporal self-information image Ĥₑ;
obtaining a fifth restored feature map by inputting the fourth restored feature map into the fourth convolutional layer, obtaining a sixth restored feature map by inputting the fifth reduced feature map into the fifth convolutional layer, obtaining a seventh restored feature map by inputting the sixth restored feature map into the sixth convolutional layer, and obtaining an eighth restored feature map by adding the fourth restored feature map and the seventh restored feature map; and
obtaining the restored temporal CSI image Ĥ_{c} by inputting the eighth restored feature image into the seventh convolutional layer for normalization.

22. (canceled)

23. The method of claim 15, further comprising:
receiving training data sent by the terminal, wherein the training data comprises a training feature codeword, a time-sequence length of a temporal self-information image Hₑ, a dimension of the training feature codeword, and a training temporal CSI image;
obtaining a restored temporal CSI image according to the training feature codeword; and
performing training according to the restored temporal CSI image and the training temporal CSI image.

24. The method of claim 23, further comprising:
determining a number of structural units in a decoupling LSTM according to the time-sequence length of the temporal self-information image Hₑ;
determining network parameters of a one-dimensional time-space decompression network according to the dimension of the training feature codeword;
performing multiple rounds of training, wherein an equation of a learning rate in the training is represented as:
$$γ = {γ}_{min} + \frac{1}{2} ( {γ}_{max} + {γ}_{min} ) [ 1 + cos ( \frac{t - {T}_{w}}{{T}^{′} - {T}_{w}} π ) ] \underline{,}$$
where γ represents a current learning rate, γₘₐₓ represents a maximum learning rate, γₘᵢₙ represents a minimum learning rate, t represents a current number of training rounds, T_{w} represents a number of gradual learnings, T′ represents a number of overall training cycles; and
obtaining recommended network parameters for a decoupling module and a restored convolutional neural network, and updating the decoupling module and the restored convolutional neural network according to the recommended network parameters.

25-28. (canceled)

29. A communication device comprising:
a processor; and
a memory having a computer program stored thereon,
wherein the processor is configured to:
obtain an estimated CSI image H of a network device, and generate a temporal CSI image H_{c} according to the estimated CSI image H;
compress the temporal CSI image H_{c} to generate a feature codeword; and
send the feature codeword to the network device.

30-34. (canceled)
